(19) United States
(12) Patent Application Publication
(10) Pub. No.: US 2026/0362798 A1
(43) Pub. Date: Nov. 12, 2026

(54) VERTICAL CHANNEL SEMICONDUCTOR DEVICE WITH TOP-SIDE DRAIN

(71) Applicant: Microchip Technology Incorporated, Chandler, AZ (US)

(72) Inventors: Shesh Mani Pandey, Gilbert, AZ (US); Fernando Estrada, Mesa, AZ (US)

(73) Assignee: Microchip Technology Incorporated, Chandler, AZ (US)

(21) Appl. No.: 19/304,315

(22) Filed: Aug. 19, 2025

Related U.S. Application Data
(60) Provisional application No. 63/802,069, filed on May 8, 2025.

(51) Int. Cl. H10D 84/83; H10D 30/66

(52) U.S. Cl. CPC H10D 84/839; H10D 30/663

(57) ABSTRACT

A semiconductor device includes a volume of semiconductor material presenting a first end, an opposing second end, and a first side extending between the first and second ends. The semiconductor device includes a first source region positioned proximate the first end, a first drain contact disposed on at least a portion of the second end, and a first isolation region extending from the first end to the second end along the first side. A first drain electrode extends through the isolation region from the first drain contact to the first end.

### CROSS REFERENCE TO RELATED APPLICATION

The present U.S. non-provisional patent application is related to and claims priority benefit of an earlier-filed U.S. provisional patent application titled “INTEGRATED BIDIRECTIONAL COMMON DRAIN MOSFET SWITCH,” Ser. No. 63/802,069, filed May 8, 2025. The entire content of the identified earlier-filed application is hereby incorporated by reference as if fully set forth herein.

### FIELD OF THE DISCLOSURE

Various examples of the present technology relate to field-effect transistors (FETs) designed for efficient, high-voltage switching in electronic systems.

### BACKGROUND OF THE DISCLOSURE

Power semiconductor devices, such as vertical channel metal oxide semiconductor field-effect transistors (MOSFETs), are utilized in high-voltage and high-current switching applications. Conventional vertical channel MOSFET structures typically position the drain contact on a bottom surface of the semiconductor die, opposite source and gate contacts. The bottom surface drain contact can complicate packaging, thermal management, and integration with surface-level interconnects.

The background discussion is intended to provide information related to the present technology which is not necessarily prior art.

### BRIEF DESCRIPTION

This brief description is provided to introduce a selection of concepts in a simplified form that are further described in the detailed description below. This brief description is not intended to identify key features or essential features of the claimed subject matter, nor is it intended to be used to limit the scope of the claimed subject matter. Other aspects and advantages of the present disclosure will be apparent from the following detailed description of the embodiments and the accompanying figures.

In various aspects, a semiconductor device is provided. the semiconductor device includes a volume of semiconductor material presenting a first end, an opposing second end, and a first side extending between the first and second ends. The semiconductor device also includes a first source region positioned proximate the first end and a first drain contact disposed on at least a portion of the second end. Furthermore, the semiconductor device includes a first isolation region extending from the first end to the second end along the first side and a first drain electrode extending through the isolation region from the first drain contact to the first end.

In various aspects, a semiconductor device is provided. The semiconductor device includes a volume of semiconductor material presenting a first end, an opposing second end, and a first side extending between the first and second ends. The semiconductor device also includes a first gate region positioned proximate the first end and a first drain contact disposed on at least a portion of the second end. Furthermore, the semiconductor device includes a first isolation region extending from the first end to the second end along the first side and a first drain electrode extending through the isolation region from the first drain contact to the first end.

A variety of additional aspects will be set forth in the detailed description that follows. These aspects can relate to individual features and to combinations of features. Advantages of these and other aspects will become more apparent to those skilled in the art from the following description of the exemplary embodiments which have been shown and described by way of illustration. As will be realized, the present aspects described herein may be capable of other and different aspects, and their details are capable of modification in various respects. Accordingly, the figures and description are to be regarded as illustrative in nature and not as restrictive.

### BRIEF DESCRIPTION OF DRAWINGS

Various examples of the current technology are described in detail below with reference to the attached drawing figures, wherein:

FIG. 1 is a schematic cross-sectional view of a bidirectional field-effect transistor (FET) constructed in accordance with various examples of the current technology, the device including two planar-gate metal oxide semiconductor FET (MOSFET) regions laterally separated by field oxide and sharing a drain;

FIG. 2 is a schematic plan view of the bidirectional FET of FIG. 1, depicting the two MOSFET regions, the drain, and the field oxide, enclosed within a single edge-termination structure;

FIG. 3 is a schematic cross-sectional view of a bidirectional field-effect transistor (FET) constructed in accordance with various examples of the current technology, the device including two planar-gate metal oxide semiconductor FET (MOSFET) regions laterally separated by field oxide and sharing a source;

FIG. 4 is a schematic plan view of the bidirectional FET of FIG. 3, depicting the two MOSFET regions, the drains, and the field oxide, enclosed within a single edge-termination structure;

FIG. 5 is a schematic cross-sectional view of a dual channel field-effect transistor (FET) constructed in accordance with various examples of the current technology, the device including two planar-gate metal oxide semiconductor FET (MOSFET) regions laterally separated by field oxide; and

FIG. 6 is a schematic cross-sectional view of a vertical channel field-effect transistor (FET) constructed in accordance with various examples of the current technology, the device including a top-side drain contact.

Unless otherwise indicated, the figures provided herein are meant to illustrate features of examples of this disclosure. These features are believed to be applicable in a wide variety of systems comprising one or more examples of this disclosure. As such, the figures are not meant to include all conventional features known by those of ordinary skill in the art to be required for the practice of the examples disclosed herein.

### DETAILED DESCRIPTION OF THE DISCLOSURE

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, and process changes may be made without departing from the scope of the disclosure.

The illustrations presented herein are not meant to be actual views of any particular method, system, device, or structure, but are merely idealized representations that are employed to describe the examples of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

Terms of relative location and direction (e.g., above, below, left, right, upper, lower, vertical, horizontal (or lateral)) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation.

The following description may include examples to help enable one of ordinary skill in the art to practice the disclosed examples. The use of the terms “exemplary,” “by example,” and “for example,” means that the related description is explanatory, and though the scope of the disclosure is intended to encompass the examples and legal equivalents, the use of such terms is not intended to limit the scope of an example or this disclosure to the specified components, operations, features, functions, or the like.

It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Broadly, examples provide a monolithic bidirectional power field-effect transistor (FET) in which two metal-oxide-semiconductor FETs (MOSFETs) are integrated side-by-side on a single die, laterally isolated by field oxide, and coupled to a common through-silicon drain electrode. The MOSFETs, field oxide, and drain electrode are all enclosed within a single edge-termination structure. Examples advantageously deliver compact, low-loss four-quadrant switching while eliminating duplicate terminations and added interconnects. As used herein, the term “monolithic” refers to the integration of all device components (i.e., both MOSFETs, the field oxide, and the common drain electrode) within a single semiconductor die during fabrication.

FETs, such as MOSFETs and junction FETs (JFETs), are semiconductor material devices that include three terminals: a gate, a drain, and a source. A voltage is applied to one of the terminals, i.e., the gate, to control current flow between the other two terminals, i.e., the drain and the source. Silicon (Si) is typically used as the semiconductor material, although in high voltage applications, silicon carbide (SiC) is utilized, resulting in a SiC power FET.

### BIDIRECTIONAL SWITCH WITH COMMON DRAIN

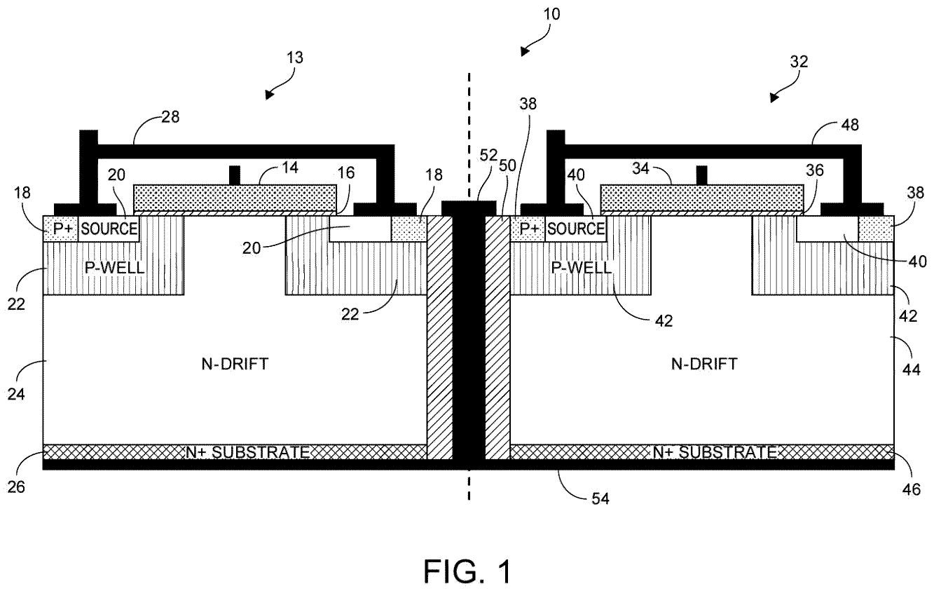

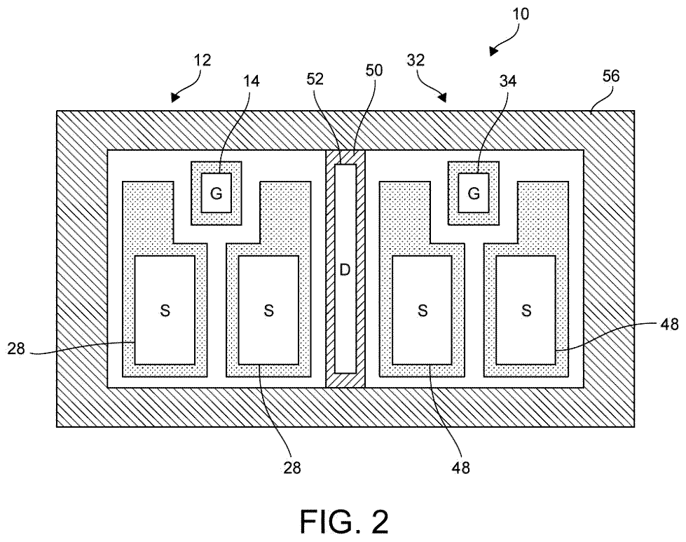

Referring to FIGS. 1 and 2, an example improved bidirectional FET 10 is shown. Examples of the FET 10 shown in the figures include a MOSFET, although the principles of the current technology apply to other active devices as well, including a JFET, in which the gate oxide layer may be omitted. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N−doped or P−doped in N-channel implementations may be, respectively, P−doped or N−doped in P-channel implementations.

The bidirectional FET 10 is a monolithic structure formed from a plurality of layers, or volume, of semiconductor material and broadly comprises two MOSFET regions 12 and 32 integrated side-by-side on a single die. In the example, the MOSFET regions 12 and 32 are substantially the same. The MOSFET regions 12 and 32 are laterally isolated by a field oxide isolation region 50 (broadly, an isolation region). The field oxide isolation region 50 permits the integration of the MOSFET regions 12 and 32 onto a single die and, consequently, reduces or removes the need for a mechanical scribe which might otherwise be used to separate the two MOSFET regions 12 and 32.

In addition, the MOSFET regions 12 and 32 are coupled to a common drain electrode 52, which may comprise a through-silicon drain electrode. The MOSFET regions 12 and 32, drain electrode 52, and oxide isolation region 50 are enclosed within a single outer edge-termination structure 56. In various examples, the common drain electrode 52 may be formed in a trench defined by and within the field oxide isolation region 50. In various examples, the trench may be etched. In various examples, the common drain electrode 52 may be a metal-filled through-silicon drain trench, i.e., a conductive material disposed in a trench defined through the oxide isolation region 50.

In the example, the first MOSFET region 12 is disposed on the left-hand side, as depicted in the figures. The first MOSFET region 12 includes a first gate 14. In various examples, the first gate 14 may be formed from polysilicon, a metal or alloy of metals, or other suitable material, and is positioned at a first, or top, end of the structure of the monolithic bidirectional FET 10 (i.e., the volume of semiconductor material). In the example first MOSFET region 12, positioned beneath the first gate 14 is a gate oxide layer 16, which may be formed from silicon dioxide, aluminum dioxide (Al₂O₃), hafnium dioxide, silicon nitride, or other suitable insulating or dielectric material.

In the first MOSFET region 12, laterally opposed semiconductor regions are located adjacent to, and extend partly beneath, the gate oxide layer 16 associated with the first gate 14. Each of the semiconductor regions includes a P-well 22, a P+ doped region 18, and an N+ source region 20. The N+ source region 20 is adjacent to the P+ doped region 18. It is noted that the structural configuration on each lateral side is substantially a mirror image of the configuration on the opposite side; accordingly, identical reference numerals are used to denote corresponding structural features.

An N-type drift region 24 lies beneath the P-wells 22 and extends upward therebetween, thereby forming a central drift region extension that extends to an interface with the gate oxide layer 16. Thus, the first gate 14 overlaps the edges of each P-well 22, N+ source region 20, and the central drift region extension interposed therebetween. The N-type drift region 24 overlies an N+ substrate segment 26 (broadly, a drain region). The N-type drift region 24 may be formed from N− doped epitaxial material.

In various examples, a first source electrode 28 (or contact) is positioned in electrical contact with at least a portion of each N+ source region 20. The N-type drift region 24 provides the primary electrical conduction path between the first source electrode 28 and the N+ substrate segment 26.

The second MOSFET region 32 is positioned on the right-hand side of the FET 10, as depicted in the figures, and is substantially the same as the first MOSFET region 12. The second MOSFET region 32 includes laterally opposed semiconductor regions that are located adjacent to, and extend partly beneath, a gate oxide layer 36 associated with a second gate 34. Each of the semiconductor regions includes a P-well 42, a P+ doped region 38, and an N+ source region 40. The N+ source region 40 is adjacent to the P+ doped region 38. It is noted that the structural configuration on each lateral side is substantially a mirror image of the configuration on the opposite side; accordingly, identical reference numerals are used to denote corresponding structural features.

An N-type drift region 44 lies beneath the P-wells 42 and extends upward therebetween, thereby forming a central drift region extension that extends to an interface with the gate oxide layer 36. Thus, the second gate 34 overlaps the edges of each P-well 42, N+ source 40, and the central drift region extension interposed therebetween. The N-type drift region 44 overlies an N+ substrate segment 46 (broadly, a drain region). The N-type drift region 44 may be formed from N− doped epitaxial material.

In various examples, a second source electrode 48 (or contact) is positioned in electrical contact with at least a portion of each N+ source region 40. The N-type drift region 44 provides the primary electrical conduction path between the second source electrode 48 and the N+ substrate segment 46.

The field oxide isolation region 50 laterally separates the two MOSFET regions 12 and 32. In addition, the field oxide isolation region 50 envelops at least a portion of the drain electrode 52, which may comprise a metal-filled trench drain electrode. The field oxide isolation region 50 extends vertically from the first end of the volume of semiconductor material to an opposing second end, passing through the N-type drift regions 24, 44 and N+ substrates 26, 46 along a side of at least one of the two MOSFET regions 12 and 32. The field oxide isolation region 50 thus divides N-type drift region 24 from N-type drift region 44, and divides N+ substrate 26 from N+ substrate 46, so the divided regions are not in direct contact with each other. In various examples, the field oxide isolation region 50 insulates electrical fields of these respective areas of the two MOSFET regions 12 and 32 from each other.

As depicted in FIGS. 1 and 2, the drain electrode 52 passes through the field oxide isolation region 50 and contacts a common backside drain metallization layer 54 (broadly, a drain contact). In various examples, the backside drain metallization layer 54 is positioned at a second, or bottom, end of the structure of the monolithic bidirectional FET 10 (i.e., the volume of semiconductor material). In various examples, the backside drain metallization layer 54 spans beneath both the N+ substrate segments 26 and 46. The backside drain metallization layer 54 is electrically coupled to the drain electrode 52, forming a common drain contact or node for the entire monolithic bidirectional FET 10.

The field oxide isolation region 50 may be formed from any insulating material compatible with fabrication of the monolithic bidirectional FET 10. In various examples, the field oxide isolation region 50 is silicon dioxide. In various other examples, the field oxide isolation region 50 may include silicon oxynitride or a stack of oxide and nitride layers. Alternative dielectric materials, such as aluminum oxide or hafnium oxide, are also suitable materials for forming the field oxide isolation region 50. The field oxide isolation region 50 may be formed by etching a trench through the N-type drift regions 24, 44, and the N+ substrates 26, 46 and filling the trench with the selected dielectric material. In various examples, a lateral thickness of the field oxide isolation region 50 is voltage dependent. Lower voltage semiconductor devices may employ a thinner dielectric layer, whereas higher voltage devices may employ a proportionally thicker dielectric layer.

Referring to FIG. 2, the monolithic bidirectional FET 10 includes the single edge-termination structure 56 (e.g., one or more guard rings, junction termination extensions (JTE), field plates, or equivalent, without limitation) that surrounds both the first and second MOSFET regions 12 and 32 and the drain or drain electrode 52, in a single closed loop. As described herein, the field oxide isolation region 50 internally isolates the two halves of the monolithic bidirectional FET 10. As such, the monolithic bidirectional FET 10 reduces the need for or avoids the addition of an intermediate termination structure between the first MOSFET region 12 and the second MOSFET region 32.

### BIDIRECTIONAL SWITCH WITH COMMON SOURCE

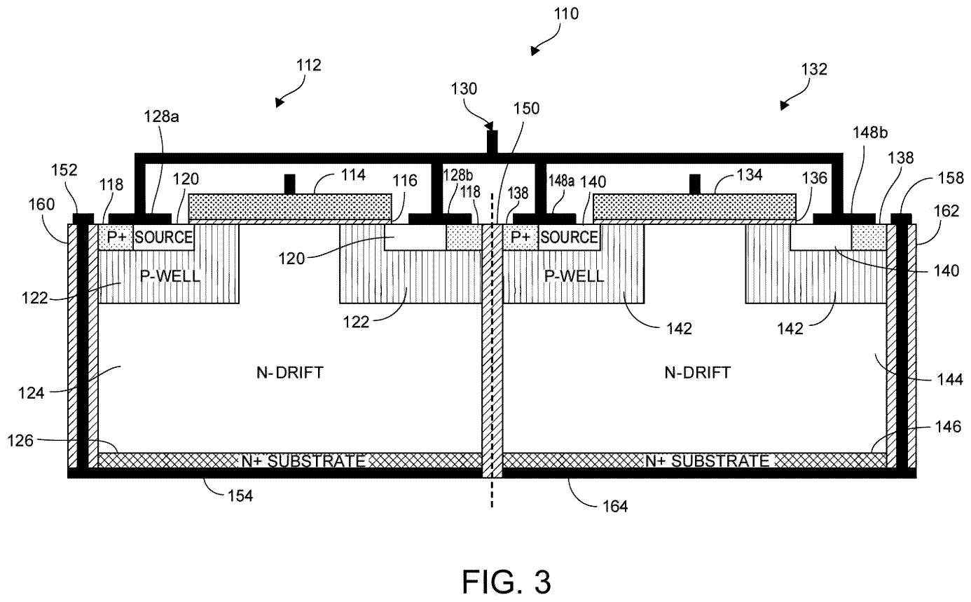

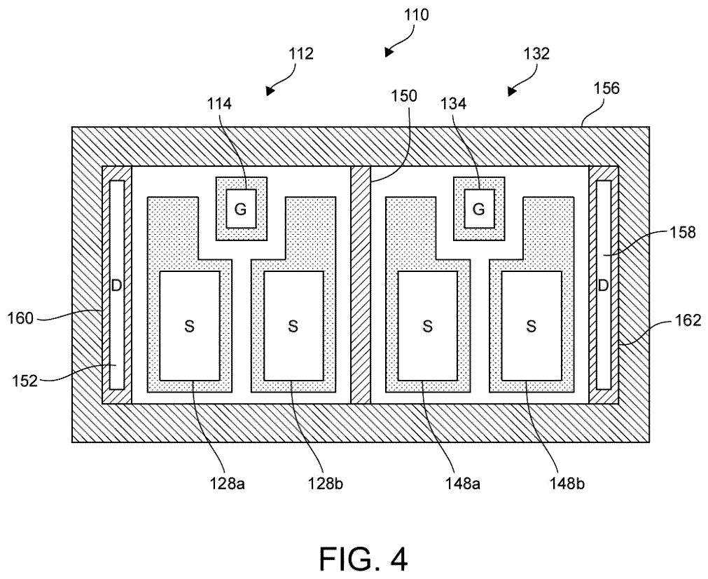

Referring to FIGS. 3 and 4, an example improved bidirectional FET 110 is shown. In the example depicted in FIG. 3, the semiconductor device architecture and many structural features correspond to those of the example bidirectional FET 10 described above in FIGS. 1 and 2. Examples of the bidirectional FET 110 shown in FIG. 3 include a MOSFET, although the principles of the current technology apply to other active devices as well, including a JFET, in which the gate oxide layer may be omitted. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N−doped or P-−doped in N-channel implementations may be, respectively, P−doped or N−doped in P-channel implementations.

The bidirectional FET 110 is a monolithic structure formed from a plurality of layers, or volume, of semiconductor material and broadly comprises two MOSFET regions 112 and 132 integrated side-by-side on a single die. In the example, the MOSFET regions 112 and 132 are substantially the same. The MOSFET regions 112 and 132 are laterally isolated by a central field oxide isolation region 150 (broadly, an isolation region). The central field oxide isolation region 150 permits the integration of the MOSFET regions 112 and 132 onto a single die and, consequently, reduces or removes the need for a mechanical scribe which might otherwise be used to separate the two MOSFET regions 112 and 132.

In the example, the first MOSFET region 112 is disposed on the left-hand side, as depicted in FIGS. 3 and 4. The first MOSFET region 112 includes a first gate 114. In various examples, the first gate 114 may be formed from polysilicon, a metal or alloy of metals, or other suitable material, and is positioned at a first, or top, end of the structure of the monolithic bidirectional FET 110 (i.e., the volume of semiconductor material). In the example first MOSFET region 112, positioned beneath the first gate 114 is a gate oxide layer 116, which may be formed from silicon dioxide, aluminum dioxide (Al₂O₃), hafnium dioxide, silicon nitride, or other suitable insulating or dielectric material.

In the first MOSFET region 112, laterally opposed semiconductor regions are located adjacent to, and extend partly beneath, the gate oxide layer 116 associated with the first gate 114. Each of the semiconductor regions includes a P-well 122, a P+ doped region 118, and an N+ source region 120. The N+ source region 120 is adjacent to the P+ doped region 118. It is noted that the structural configuration on each lateral side is substantially a mirror image of the configuration on the opposite side; accordingly, identical reference numerals are used to denote corresponding structural features.

An N-type drift region 124 lies beneath the P-wells 122 and extends upward therebetween, thereby forming a central drift region extension that extends to an interface with the gate oxide layer 116. Thus, the first gate 114 overlaps the edges of each P-well 122, N+ source region 120, and the central drift region extension interposed therebetween. The N-type drift region 124 overlies an N+ substrate segment 126 (broadly, a drain region). The N-type drift region 124 may be formed from N− doped epitaxial material.

The second MOSFET region 132 is positioned on the right-hand side of the FET 110, as depicted in the figures, and is substantially the same as the first MOSFET region 112. The second MOSFET region 132 includes laterally opposed semiconductor regions that are located adjacent to, and extend partly beneath, a gate oxide layer 136 associated with the second gate 134. Each region includes a P-well 142, a P+ doped region 138, and an N+ source region 140. The N+ source region 140 is adjacent to the P+ doped region 138. It is noted that the structural configuration on each lateral side is substantially a mirror image of the configuration on the opposite side; accordingly, identical reference numerals are used to denote corresponding structural features.

An N-type drift region 144 lies beneath the P-wells 142 and extends upward therebetween, thereby forming a central drift region extension that extends to an interface with the gate oxide layer 136. Thus, the second gate 134 overlaps the edges of each P-well 142, N+ source 140, and the central drift region extension interposed therebetween. The N-type drift region 144 overlies an N+ substrate segment 146 (broadly, a drain region). The N-type drift region 144 may be formed from N− doped epitaxial material.

In various examples, the monolithic bidirectional FET 110 includes a source 130. The source 130 includes one or more first contacts 128a, 128b electrically coupled to at least a portion of the first N+ source regions 120. The source 130 also includes one or more second contacts 148a, 148b electrically coupled to at least a portion of the second N+source regions 140. In various examples, the N-type drift region 124 provides the primary electrical conduction path between the first source electrodes 128a, 128b and the N+ substrate segment 126. The N-type drift region 144 provides the primary electrical conduction path between the second source electrodes 148a, 148b and the N+ substrate segment 146.

As described above, the central field oxide isolation region 150 laterally separates the two MOSFET regions 112 and 132. In various examples, the central field oxide isolation region 150 extends vertically along a side of at least one of the two MOSFET regions 112 and 132 from the first end of the volume of semiconductor material to an opposing second end. As depicted in FIG. 3, the central field oxide isolation region 150 passes through the N-type drift regions 124, 144; the substrate layers 126, 146; and backside drain metallization layers 154, 164. The field oxide isolation region 150 thus divides the respective N-type drift region 124 from the N-type drift region 144; divides the substrate layer 126 from the substrate layer 146; and divides the backside drain metallization layer 154 from the metallization layer 164, so the divided regions/layers are not in direct contact with each other. In various examples, the field oxide isolation region 150 insulates electrical fields of these respective areas of the two MOSFET regions 112 and 132 from each other.

In various examples, the MOSFET region 112 includes a field oxide isolation region 160 on a side of the MOSFET region 112 opposite the central field oxide isolation region 150. The field oxide isolation region 160 extends vertically from the first end of the volume of semiconductor material to the opposing second end, passing through the N-type drift region 124 and the substrate layer 126.

In addition, the MOSFET region 112 is coupled to a drain electrode 152. The drain electrode 152 may comprise a through-silicon drain electrode. The drain electrode 152 may be formed in a trench defined by and within the field oxide isolation region 160. In various examples, the trench may be etched. In various examples, the drain electrode 152 may be a metal-filled through-silicon drain trench, i.e., a conductive material disposed in the trench defined through the field oxide isolation region 160.

In various examples, the MOSFET region 132 includes a field oxide isolation region 162 on a side of the MOSFET region 132 opposite the central field oxide isolation region 150. The field oxide isolation region 162 extends vertically from the first end of the volume of semiconductor material to the opposing second end, passing through the N-type drift region 144 and the substrate layer 146.

In addition, the MOSFET region 132 is coupled to a drain electrode 158. The drain electrode 158 may comprise a through-silicon drain electrode. The drain electrode 158 may be formed in a trench defined by and within the field oxide isolation region 162. In various examples, the trench may be etched. In various examples, the drain electrode 158 may be a metal-filled through-silicon drain trench, i.e., a conductive material disposed in the trench defined through the field oxide isolation region 162.

As depicted in FIG. 3, the drain electrode 152 passes through the field oxide isolation region 160 and contacts the backside drain metallization layer 154 (broadly, a drain contact). In various examples, the backside drain metallization layer 154 is positioned at the second, or bottom, end of the structure of the monolithic bidirectional FET 110 (i.e., the volume of semiconductor material). In various examples, the backside drain metallization layer 154 spans beneath at least a portion of the N+ substrate segment 126. The backside drain metallization layer 154 is electrically coupled to the drain electrode 152, thereby forming a drain contact or node for the MOSFET region 112.

The drain electrode 158 passes through the field oxide isolation region 162 and contacts the backside drain metallization layer 164 (broadly, a drain contact). In various examples, the backside drain metallization layer 164 is positioned at the second, or bottom, end of the structure of the monolithic bidirectional FET 110 (i.e., the volume of semiconductor material). In various examples, the backside drain metallization layer 164 spans beneath at least a portion of the N+ substrate segment 146. The backside drain metallization layer 164 is electrically coupled to the drain electrode 158, thereby forming a drain contact or node for the MOSFET region 132.

The central field oxide isolation region 150, the field oxide isolation region 160, and the field oxide isolation region 162 may be formed from any insulating material compatible with fabrication of the monolithic bidirectional FET 110. In various examples, the field oxide isolation regions 150, 160, and 162 are silicon dioxide. In various other examples, the field oxide isolation regions 150, 160, and 162 may include silicon oxynitride or a stack of oxide and nitride layers. Alternative dielectric materials, such as aluminum oxide or hafnium oxide, are also suitable materials for forming the field oxide isolation regions. Each of the field oxide isolation regions 150, 160, and 162 may be formed by etching a trench through one or more of the N-type drift regions 124, 144, and the N+ substrates 126, 146 and filling the trench with the selected dielectric material. In various examples, a lateral thickness of the respective field oxide isolation regions 150, 160, and 162 is voltage dependent. Lower voltage semiconductor devices may employ a thinner dielectric layer, whereas higher voltage devices may employ a proportionally thicker dielectric layer.

As shown in FIG. 4, in various examples, the MOSFET regions 112 and 132, drain electrodes 152 and 158, and the central oxide isolation region 150 are enclosed within a single outer edge-termination structure 156. The single edge-termination structure 156 may include, for example, and without limitation, one or more guard rings, junction termination extensions (JTE), field plates, or equivalent, that surround both the first and second MOSFET regions 112 and 132, the central field oxide isolation region 150, and the drain electrodes 152 and 158 in a single closed loop. As described herein, the central field oxide isolation region 150 internally isolates the two halves of the monolithic bidirectional FET 110. As such, the monolithic bidirectional FET 110 avoids the addition of an intermediate termination structure between the first MOSFET region 112 and the second MOSFET region 132.

### MONOLITHIC DUAL CHANNEL FIELD-EFFECT TRANSISTOR

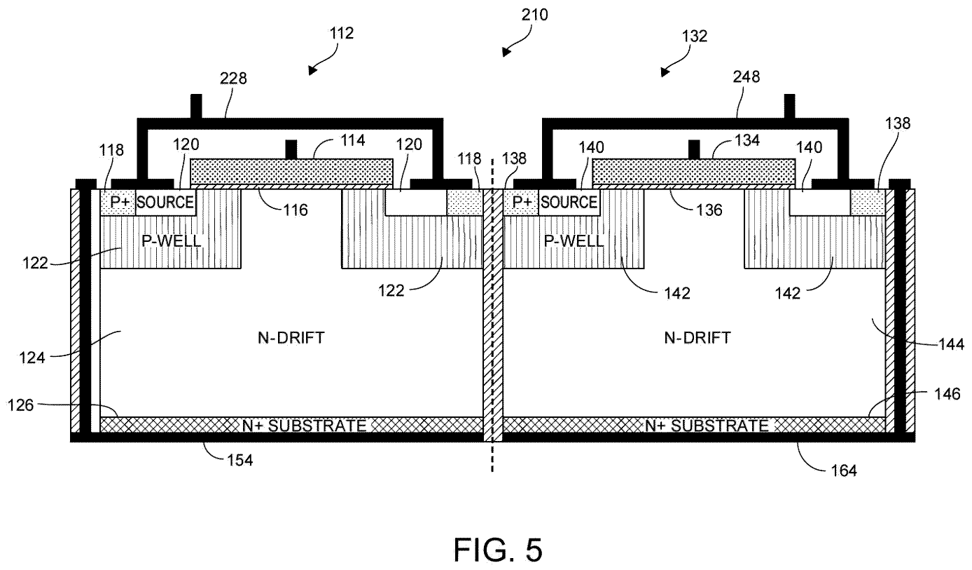

Referring to FIG. 5, an example improved monolithic dual channel FET 210 is shown. In the example depicted in FIG. 5, the semiconductor device architecture and most structural features correspond directly to those of the example bidirectional FET 110 described above in FIGS. 3 and 4 (and are accordingly identified by the same reference numerals). For brevity, only the structural features that differ from the example depicted in FIGS. 3 and 4 are discussed in detail below. All other aspects are to be understood as identical or equivalent.

As depicted in FIG. 5, in various examples, the monolithic dual channel FET 210 includes two (2) independent source electrodes rather than the single source 130 depicted in FIG. 3. Thus, in the example, the first MOSFET region 112 includes a first source electrode 228 (or contact) positioned in electrical contact with at least a portion of each of the N+ source regions 120. The N-type drift region 124 provides the primary electrical conduction path between the first source electrode 228 and the N+ substrate segment 126. The second MOSFET region 132 includes a second source electrode 248 (or contact) positioned in electrical contact with at least a portion of each of the N+ source regions 140. The N-type drift region 144 provides the primary conduction path between the second source electrode 248 and the N+ substrate segment 146.

The improved monolithic dual channel FET 210, having two (2) independent FETs integrated side-by-side on a single semiconductor die and laterally isolated, facilitates reducing overall die size and packaging complexity by reducing or eliminating the need for two separate discrete devices.

### VERTICAL CHANNEL FIELD-EFFECT TRANSISTOR WITH TOP-SIDE DRAIN

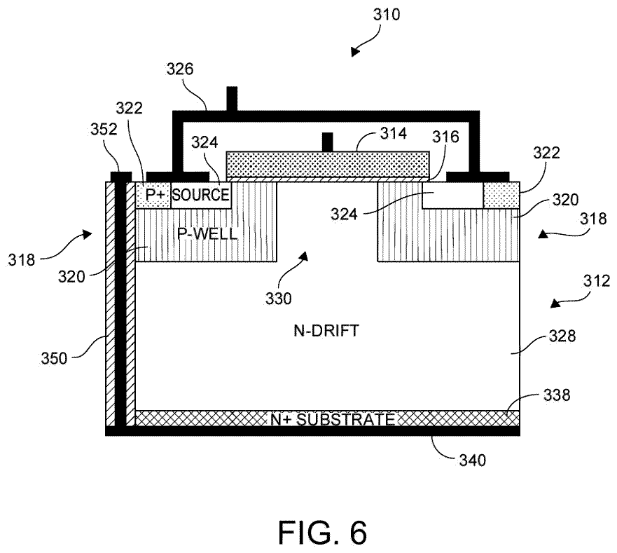

Referring to FIG. 6, an example improved vertical channel FET 310 is shown. Examples of the FET 310 shown in FIG. 6 include a MOSFET, although the principles of the current technology apply to other active devices as well, including a JFET, in which the gate oxide layer may be omitted. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N−doped or P−doped in N-channel implementations may be, respectively, P−doped or N−doped in P-channel implementations.

In various examples, the FET 310 comprises a volume of semiconductor material 312 forming a plurality of doped regions discussed in more detail below. In the example, the FET 310 includes a gate 314. In various examples, the gate 314 may be formed from polysilicon, a metal or alloy of metals, or other suitable material, and is positioned at a first, or top, end of the structure of the FET 310. In the example FET 310, positioned beneath the gate 314 is a gate oxide layer 316, which may be formed from silicon dioxide, aluminum dioxide, hafnium dioxide, silicon nitride, or other suitable insulating or dielectric material.

In the example FET 310, laterally opposed semiconductor regions 318 are located adjacent to, and extend partly beneath, the gate oxide layer 316. Each of the semiconductor regions 318 includes a P-well 320 (doped p-type semiconductor material), a P+ region 322 (doped p-type semiconductor material), and an N+ source region 324 (doped n-type semiconductor material). The N+ source region 324 is adjacent to the P+region 322. It is noted that the structural configuration on each lateral side is substantially a mirror image of the configuration on the opposite side; accordingly, identical reference numerals are used to denote corresponding structural features.

An N-drift region 328 (doped n-type semiconductor material) lies beneath the P-wells 320 and extends upward therebetween, thereby forming a central drift region 330 that extends to an interface between the volume of semiconductor material 312 and the gate oxide layer 316. The gate 314 overlaps edges of each P-well 320, each N+ source region 324, and the central drift region 330. The N-drift region 328 overlies an N+ substrate 338 (doped n-type semiconductor material), which functions broadly as a drain region.

A source electrode 326 (or contact) is positioned in electrical contact with at least a portion of each N+ source region 324. The N-drift region 328 provides the primary electrical conduction path between the source electrode 326 and the N+ substrate 338. The N+ substrate 338 overlies a backside drain contact 340.

In various examples, the FET 310 includes a field oxide isolation region 350 extending along a side of the FET 310. The field oxide isolation region 350 extends vertically from the first end of the volume of semiconductor material 312 to the opposing second end, passing through the N-drift region 328 and the N+ substrate 338.

In addition, the FET 310 includes a drain electrode 352. The drain electrode 352 may comprise a through-silicon drain electrode. The drain electrode 352 may be formed in a trench defined by and within the field oxide isolation region 350. In various examples, the trench may be etched. In various examples, the drain electrode 352 may be a metal-filled through-silicon drain trench, i.e., a conductive material disposed in the trench defined through the field oxide isolation region 350.

As depicted in FIG. 6, the drain electrode 352 passes through the field oxide isolation region 350 and contacts the backside drain contact 340. In various examples, the backside drain contact 340 is positioned at the second, or bottom, end of the volume of semiconductor material 312 forming the structure of the FET 310. The backside drain contact 340 is electrically coupled to the drain electrode 352, forming a drain contact or node for the FET 310.

The field oxide isolation region 350 may be formed from any insulating material compatible with fabrication of the FET 310. In various examples, the field oxide isolation region 350 is silicon dioxide. In various other examples, the field oxide isolation region 350 may include silicon oxynitride or a stack of oxide and nitride layers. Alternative dielectric materials, such as aluminum oxide or hafnium oxide, are also suitable materials for forming the field oxide isolation region 350. The field oxide isolation region 350 may be formed by etching a trench through one or more of the N-drift region 328 and the N+ substrate 338 and filling the trench with the selected dielectric material. In various examples, a lateral thickness of the field oxide isolation region 350 is voltage dependent. Lower voltage semiconductor devices may employ a thinner dielectric layer, whereas higher voltage devices may employ a proportionally thicker dielectric layer.

### FEATURE COMBINATIONS

In accordance with various examples of the present disclosure, a semiconductor device may include a volume of semiconductor material having a first end, an opposing second end, and a first side extending between the first and second ends. The semiconductor device may further include a first source region located proximate the first end, a first drain contact disposed on at least a portion of the second end, a first isolation region extending longitudinally along the first side from the first end to the second end, and a first drain electrode that extends through the isolation region from the first drain contact toward the first end.

In combination with the previously described examples, the semiconductor device may further include a second source region positioned proximate the first end, where the first isolation region laterally separates the first and second source regions, and the first drain contact operates as a common drain contact for both the first and second source regions.

In accordance with any previously described examples, the first drain electrode may include a conductive material disposed within a trench defined by the first isolation region.

In accordance with any previously described examples, the semiconductor device may further include a second source region positioned proximate the first end, and first and second source contacts located proximate the first end and respectively coupled to the first and second source regions.

Additionally, the semiconductor device, in combination with any previously described examples, may further include a second source region positioned proximate the first end, and an edge-termination structure that surrounds the first and second source regions and the first isolation region in a closed loop configuration.

According to various other examples, the semiconductor device may include a second source region positioned laterally adjacent the first source region, a central isolation region laterally separating these first and second source regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact to the first end. In this configuration, the first drain contact acts as a first drain terminal for the first source region, and the second drain contact acts as a second drain terminal for the second source region, with the first and second drain contacts being electrically isolated from each other.

Consistent with previously described examples, the semiconductor device may include a second source region positioned laterally adjacent the first source region, a central isolation region laterally separating these first and second source regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact to the first end. In this configuration, the first drain contact acts as a first drain terminal for the first source region, and the second drain contact acts as a second drain terminal for the second source region, with the first and second drain contacts being electrically isolated from each other. The first drain electrode may include a first conductive material disposed in a first trench defined by the first isolation region, while the second drain electrode may include a second conductive material disposed in a second trench defined by the second isolation region.

In accordance with the examples previously discussed, the semiconductor device may include a second source region positioned laterally adjacent the first source region, a central isolation region laterally separating these first and second source regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact to the first end. In this configuration, the first drain contact acts as a first drain terminal for the first source region, and the second drain contact acts as a second drain terminal for the second source region, with the first and second drain contacts being electrically isolated from each other. The semiconductor device may further include an edge-termination structure surrounding the first and second source regions, the first and second isolation regions, and the central isolation region, forming a closed loop.

Additionally, the semiconductor device, in combination with the previously mentioned examples, may include a second source region positioned laterally adjacent the first source region, a central isolation region laterally separating these first and second source regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact to the first end. In this configuration, the first drain contact acts as a first drain terminal for the first source region, and the second drain contact acts as a second drain terminal for the second source region, with the first and second drain contacts being electrically isolated from each other. The semiconductor device may also include a source having first and second contacts respectively electrically coupled to the first and second source regions.

Further, consistent with any of the previously described examples, the semiconductor material may include silicon carbide.

In alternative examples, a semiconductor device may include a volume of semiconductor material with a first end, an opposing second end, and a first side extending between the first and second ends, a first gate region positioned proximate the first end, a first drain contact disposed on at least a portion of the second end, a first isolation region extending from the first end to the second end along the first side, and a first drain electrode extending through the isolation region from the first drain contact toward the first end.

According to additional alternative examples, the semiconductor device may further include a second gate region positioned proximate the first end, wherein the first isolation region laterally separates the first and second gate regions, and the first drain contact functions as a common drain contact for both the first and second gate regions.

Further alternative examples may specify that the first drain electrode comprises a conductive material disposed within a trench defined by the first isolation region.

Consistent with previously described alternative examples, the semiconductor device may further include a second gate region positioned proximate the first end, wherein the first isolation region laterally separates the first and second gate regions, and the first drain contact functions as a common drain contact for both the first and second gate regions. The semiconductor device may also include a gate contact positioned proximate the first end and electrically coupled to the first and second gate regions.

Moreover, the semiconductor device, in accordance with previously described alternative examples, may further include a second gate region positioned proximate the first end, wherein the first isolation region laterally separates the first and second gate regions, and the first drain contact functions as a common drain contact for both the first and second gate regions. The semiconductor device may also include an edge-termination structure surrounding the first and second gate regions and the isolation region in a closed loop arrangement.

In other illustrative alternative examples, the semiconductor device may include a second gate region disposed laterally adjacent to the first gate region, a central isolation region laterally separating the first and second gate regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact toward the first end. Here, the first drain contact serves as a first drain terminal for the first gate region, and the second drain contact serves as a second drain terminal for the second gate region, with electrical isolation between the first and second drain contacts.

In accordance with the previously discussed alternative examples, the semiconductor device may include a second gate region disposed laterally adjacent to the first gate region, a central isolation region laterally separating the first and second gate regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact toward the first end. Here, the first drain contact serves as a first drain terminal for the first gate region, and the second drain contact serves as a second drain terminal for the second gate region, with electrical isolation between the first and second drain contacts. The first drain electrode may include a first conductive material disposed within a first trench defined by the first isolation region, and the second drain electrode may include a second conductive material disposed within a second trench defined by the second isolation region.

Furthermore, the semiconductor device, in accordance with previously described alternative examples, may include a second gate region disposed laterally adjacent to the first gate region, a central isolation region laterally separating the first and second gate regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact toward the first end. Here, the first drain contact serves as a first drain terminal for the first gate region, and the second drain contact serves as a second drain terminal for the second gate region, with electrical isolation between the first and second drain contacts. The semiconductor device may also include an edge-termination structure, as described in previous examples, surrounding the first and second gate regions, the first and second isolation regions, and the central isolation region in a closed loop.

According to additional illustrative alternative examples, the semiconductor device may include a second gate region disposed laterally adjacent to the first gate region, a central isolation region laterally separating the first and second gate regions and spaced laterally from the first isolation region, a second drain contact disposed on at least a portion of the second end, a second isolation region extending from the first end to the second end and spaced laterally from the first and central isolation regions, and a second drain electrode extending through the second isolation region from the second drain contact toward the first end. Here, the first drain contact serves as a first drain terminal for the first gate region, and the second drain contact serves as a second drain terminal for the second gate region, with electrical isolation between the first and second drain contacts. The semiconductor device may further comprise a first source region positioned proximate the first end, a second source region laterally adjacent to the first source region and proximate the first end, and a source having first and second contacts respectively electrically coupled to these first and second source regions.

In accordance with previously described examples, the semiconductor material of the semiconductor device may comprise silicon carbide.

### GENERAL CONSIDERATIONS

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure. For example, although described herein with regard or in relation to one or more particular kinds of electronic devices (e.g., field-effect transistors), the technology may be more broadly applicable to one or more other kinds of electronic devices as well.

In this description, references to “one embodiment”, “an embodiment”, “embodiments”, “an example”, “one example”, or “examples” mean that the feature or features being referred to are included in at least one embodiment or example of the technology. Separate references to “one embodiment”, “an embodiment”, “embodiments”, “an example”, “one example”, or “examples” in this description do not necessarily refer to the same embodiment or example and are also not mutually exclusive unless so stated and/or except as will be readily apparent to those skilled in the art from the description. For example, a feature, structure, act, etc. described in one embodiment may also be included in other embodiments but is not necessarily included. Thus, the current technology can include a variety of combinations and/or integrations of the embodiments described herein.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein, unless otherwise expressly stated and/or readily apparent to those skilled in the art from the description.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

The patent claims at the end of this patent application are not intended to be construed under 35 U.S.C. § 112(f) unless traditional means-plus-function language is expressly recited, such as “means for” or “step for” language being explicitly recited in the claim(s).

1. A semiconductor device comprising:
a volume of semiconductor material presenting a first end, an opposing second end, and a first side extending between the first and second ends;
a first source region positioned proximate the first end;
a first drain contact disposed on at least a portion of the second end;
a first isolation region extending from the first end to the second end along the first side; and
a first drain electrode extending through the isolation region from the first drain contact to the first end.

2. The semiconductor device of claim 1, further comprising:
a second source region positioned proximate the first end;
the first isolation region laterally separating the first and second source regions; and
the first drain contact operative as a common drain contact for the first and second source regions.

3. The semiconductor device of claim 1,
the first drain electrode comprising a conductive material disposed in a trench defined by the first isolation region.

4. The semiconductor device of claim 2, further comprising:
a first source contact located proximate the first end and coupled to the first source region; and
a second source contact located proximate the first end and coupled to the second source region.

5. The semiconductor device of claim 2, further comprising an edge-termination structure that surrounds the first and second source regions and the first isolation region in a closed loop.

6. The semiconductor device of claim 1, further comprising:
a second source region disposed laterally adjacent the first source region;
a central isolation region laterally separating the first and second source regions, the central isolation region spaced laterally from the first isolation region;
a second drain contact disposed on at least a portion of the second end;
a second isolation region extending from the first end to the second end, the second isolation region spaced laterally from the first and central isolation regions; and
a second drain electrode extending through the second isolation region from the second drain contact to the first end;
the first drain contact operative as a first drain terminal for the first source region;
the second drain contact operative as a second drain terminal for the second source region; and
the first and second drain contacts being electrically isolated from each other.

7. The semiconductor device of claim 6,
the first drain electrode comprising a first conductive material disposed in a first trench defined by the first isolation region; and
the second drain electrode comprising a second conductive material disposed in a second trench defined by the second isolation region.

8. The semiconductor device of claim 6, further comprising an edge-termination structure that surrounds the first and second source regions, the first and second isolation regions, and the central isolation region in a closed loop.

9. The semiconductor device of claim 6, further comprising a source having first and second contacts respectively electrically coupled to the first and second source regions.

10. The semiconductor device of claim 1,
the semiconductor material comprising silicon carbide.

11. A semiconductor device comprising:
a volume of semiconductor material presenting a first end, an opposing second end, and a first side extending between the first and second ends;
a first gate region positioned proximate the first end;
a first drain contact disposed on at least a portion of the second end;
a first isolation region extending from the first end to the second end along the first side; and
a first drain electrode extending through the isolation region from the first drain contact to the first end.

12. The semiconductor device of claim 11, further comprising:
a second gate region positioned proximate the first end;
the first isolation region laterally separating the first and second gate regions; and
the first drain contact operative as a common drain contact for the first and second gate regions.

13. The semiconductor device of claim 11,
the first drain electrode comprising a conductive material disposed in a trench defined by the first isolation region.

14. The semiconductor device of claim 12, further comprising a gate contact located proximate the first end and coupled to the first and second gate regions.

15. The semiconductor device of claim 12, further comprising an edge-termination structure that surrounds the first and second gate regions and the first isolation region in a closed loop.

16. The semiconductor device of claim 11, further comprising:
a second gate region disposed laterally adjacent the first gate region;
a central isolation region laterally separating the first and second gate regions, the central isolation region spaced laterally from the first isolation region;
a second drain contact disposed on at least a portion of the second end;
a second isolation region extending from the first end to the second end, the second isolation region spaced laterally from the first and central isolation regions; and
a second drain electrode extending through the second isolation region from the second drain contact to the first end;
the first drain contact operative as a first drain terminal for the first gate region;
the second drain contact operative as a second drain terminal for the second gate region; and
the first and second drain contacts being electrically isolated from each other.

17. The semiconductor device of claim 16,
the first drain electrode comprising a first conductive material disposed in a first trench defined by the first isolation region; and
the second drain electrode comprising a second conductive material disposed in a second trench defined by the second isolation region.

18. The semiconductor device of claim 16, further comprising an edge-termination structure that surrounds the first and second gate regions, the first and second isolation regions, and the central isolation region in a closed loop.

19. The semiconductor device of claim 16, further comprising:
a first source region positioned proximate the first end;
a second source region positioned proximate the first end laterally adjacent the first source region; and
a source having first and second contacts respectively electrically coupled to the first and second source regions.

20. The semiconductor device of claim 11,
the semiconductor material comprising silicon carbide.
